(19) United States
(12) Patent Application Publication
(10) Pub. No.: US 2011/0027407 A1
(43) Pub. Date: Feb. 3, 2011

(54) PROFILE CONTROL UTILIZING A RECESSED IMPRINT TEMPLATE

(75) Inventors: Kim Yang Lee, Fremont, CA (US); David S. Kuo, Palo Alto, CA (US); Zhaoning Yu, Mountain View, CA (US)

Correspondence Address: SEAGATE TECHNOLOGY Outside Counsel Dergosits;& Noah LLP, Three Embarcadero Center, Suite 410, San Francisco, CA, 94111, US

(73) Assignee: Seagate Technology LLC, Scotts Valley, CA (US)

(21) Appl. No.: 12/510,894

(22) Filed: Jul. 28, 2009

(51) Int. Cl. B29C 59/00; B44C 1/22; C23F 1/00; G03F 7/20

(52) U.S. Cl. 425/470; 216/41; 216/2; 216/40; 430/296

(57) ABSTRACT

An imprint template is provided with a shallower field bordering the patterned region. The shallower field can be formed with additional lithography/etch steps after (or before) the formation of the features in the patterned region. The template is used to establish a thin film pattern with a field thickness that is shallower than the pattern. A shallower field bordering the patterned region alleviates sidewall re-deposition during ion mill. In a planarization/etch-back process, a thinner field helps to achieve a flat top surface by compensating for the thickness variation caused by different filling ratios. Fabrication of the recessed field template comprises a multi-step patterning process. The initial patterns are formed using a convention fabrication process. A second patterning step is used to reduce the height of the field region, which can be applied by coating the “half-finished” template with a suitable resist pattern and patterning the resist using a second lithography step that is aligned to the original pattern. Template material in the field region is then etched with the resist as a mask, forming a template with a recessed field region after the remaining resist is removed. It should be appreciated that the order of these etch steps can be reversed to obtain the same result.

### FIELD OF THE INVENTION

The present invention relates generally to imprint lithography. In particular, the invention provides an imprint template having a recessed field region such that imprinting utilizing the template produces a resist profile having significantly shallower resist thickness in the field region. Shallower resist thickness in the field region improves pattern transfer by minimizing material re-deposition during ion milling and by producing a flat surface in a planarization/etch-back process.

### BACKGROUND OF THE INVENTION

Imprint lithography (thermal and UV-curable) is known as a low cost alternative for patterning features in the surface of a substrate or workpiece. A conventional imprint lithographic process for forming nano-dimensioned features in a substrate surface is illustrated by FIGS. 1A-1D.

FIG. 1A shows a mold 10 that includes a main (or support) body 12 having upper and lower opposed surfaces and a molding layer 14 formed on the lower surface of the main body 12. As shown in FIG. 1A, molding layer 14 includes a plurality of features 16 that have a desired shape or surface contour. A substrate 18 having a thin film layer 20, formed on its upper surface is positioned below and in facing relation to the molding layer 14. Thin film layer 20, typically a commercially available resist well known to those skilled in the art, is formed on the surface of the substrate 18 by any appropriate well-known technique, e.g., by spin coating or by drop dispensing.

FIG. 1B shows a compressive molding step wherein the mold 10 is pressed into the thin film layer 20 in the direction shown by arrow 22 to form depressed, i.e., compressed, regions 24. In FIG. 1B, features 16 of the molding layer 14 are not pressed all of the way into the thin film layer 20 and thus do not contact the surface of the underlying substrate 18. However, the top surface portions 24a of the thin film 20 can contact depressed surface portions 16a of the molding layer 14. As a consequence, the top surface portions 24a substantially conform to the shape of the depressed surface portions 16a, as for example, a flat surface. When contact between the depressed surface portions 16a of the molding layer 14 and the thin film layer 20 occurs, further movement of the molding layer 14 into the thin film layer 20 stops, due to the increase in contact area, leading to a decrease in compressive pressure when the compressive force is constant.

FIG. 1C shows the cross-sectional surface contour of the thin film layer 20 following removal of mold 10. The molded, or imprinted, thin film layer 20 includes a plurality of recesses formed at compressed regions 24 which generally conform to the shape or surface contour of features 16 of the molding layer 14.

Referring to FIG. 1D, in a next step, the surface-molded thin film layer 20 is subjected to processing to remove the compressed portions 24 of the thin film layer 20 to selectively expose portions 28 of the underlying substrate 18 separated by raised features 26. Selective removal of the compressed portions 24 may be accomplished by any appropriate well known process, e.g., by reactive ion etching (RIE) or wet chemical etching.

The above-described imprint lithographic processing is capable of providing sub-10 nm dimensioned features by employing a mold 10 provided with features 16, such as pillars, holes and trenches, patterned by means of e-beam lithography, RIE, or other appropriate well known patterning methods. The material of the molding layer 14 is typically selected to be hard relative to the thin film layer 20, the latter typically comprising a thermoplastic material which is softened when heated or a UV-curable monomer that is liquid at room temperature and cured by UV exposure. Suitable materials for use as the molding layer 14 include metals, dielectrics, semiconductors, ceramics, and composite materials. Suitable materials for use as the thin film layer 20 include thermoplastic polymers which can be heated to above their glass temperature, such that the material exhibits low viscosity and enhanced flow.

After the pattern is established by imprinting the thin film layer 20 using the imprint template 14 as described above, the pattern is transferred to the underlying substrate 18 by an ion milling or by a planarization/etch-back process.

As shown in FIG. 2A, it is well know that an ion mill process will cause the thin film (resist) layer 20 to be etched faster in the patterned region than in the non-patterned (field) region, resulting in re-deposition of sputtered material 200 on the sidewalls of the thin film layer 20 bordering the patterned region (the so-called “fencing” problem). Re-deposition occurs to a lesser extent in the patterned region because this structure is more open. Sputtered material re-deposition on the sidewalls of the thin film layer 20 during ion milling should be reduced to achieve, for example, the required flyability for bit patterned media (BPM) and discrete track recording (DTR) media. Studies indicate that the degree of re-deposition is related to resist feature aspect ratio.

As shown in FIG. 2B, in a planarization/etch-back process, a planarizing material 202 is applied on the patterned thin film layer 20 after imprinting, typically by spin-coating, drop dispensing, sputtering, evaporation or other suitable deposition techniques. Due to the difference in filling ratios, a “step” profile is usually formed at the pattern/field transition region, the patterned region 204 of the planarizing material 202 being significantly shallower than its field region 206.

In view of the above, there exists a need for improved methods and means for performing imprint lithography that eliminate, or at least substantially reduce, material re-deposition during ion milling and the step profile at the pattern/field border in a planarization/etch-back process.

### SUMMARY OF THE INVENTION

The present invention provides an imprint template with a shallower field region bordering the patterned region. The shallower field can be formed with additional lithography/etch steps after (or before) the formation of the features in the patterned region. The template is used to establish a pattern in a thin film layer with a field thickness that is shallower than the patterned region. A shallower field bordering the patterned region minimizes sidewall re-deposition during ion mill. In a planarization/etch-back process, a thinner field helps to achieve a flat top surface by compensating for the thickness variation caused by different filling ratios.

Fabrication of the recessed field template comprises a multi-step patterning process. The initial pattern is formed using a convention template fabrication process, such as, for example, e-beam lithography, lift-off, etch or direct-etch. A second patterning step is used to reduce the height of the field region, which can be applied by coating the “half-finished” template with a suitable resist pattern and patterning the resist using a second lithography step that is aligned to the original pattern. Template material in the field region is then etched with the resist as a mask, forming a template with a recessed field after the remaining resist is removed.

Those skilled in the art will appreciate that the etch steps can be reversed in order. That is, the interior region can be masked and the field region etched to a first depth. Then the mask is removed and the interior region is patterned to include at least one feature that extends to a second depth that is greater than the first depth, thereby providing a template with a recessed field region.

Additional features and advantages of the present invention will become readily apparent to those skilled in the art from the following detailed description of the invention, wherein only preferred embodiments are shown and described by way of illustration of the best mode contemplated for carrying out the invention. As will be realized by those skilled in the art, the present invention is capable of other and different embodiments, and its several details are capable of modifications in various respects, all without departing from the present invention. Accordingly, the drawings and description provided herein should be regarded as illustrative, not restrictive.

### BRIEF DESCRIPTION OF THE DRAWINGS

The following detailed description of the embodiments of the present invention can best be understood when read in conjunction with the following drawings, in which the features are not necessarily drawn to scale, but rather are drawn to best illustrate the pertinent features.

FIGS. 1A-1D are schematic cross-sectional views illustrating a process sequence for performing imprint lithography of a thin film on a substrate according to the conventional art.

FIG. 2A is a schematic cross-sectional view illustrating the fencing problem caused by sputtered material re-deposition during ion mill in a conventional method for performing imprint lithography.

FIG. 2B is a schematic cross-section view illustrating the step problem that occurs in a planarization/etch-back in a conventional method for performing imprint lithography.

FIGS. 3A-3D are schematic cross-sectional views illustrating a process sequence for forming an imprint template with a recessed field region in accordance with the concepts of the present invention.

FIG. 4 provides schematic cross-sectional views illustrating the advantages of a recessed imprint template in accordance with the present invention versus a conventional imprint template in an ion mill process.

FIG. 5 provides schematic cross-sectional views illustrating the advantages of a recessed imprint template in accordance with the present invention versus a conventional imprint template in a planarization/etch-back process.

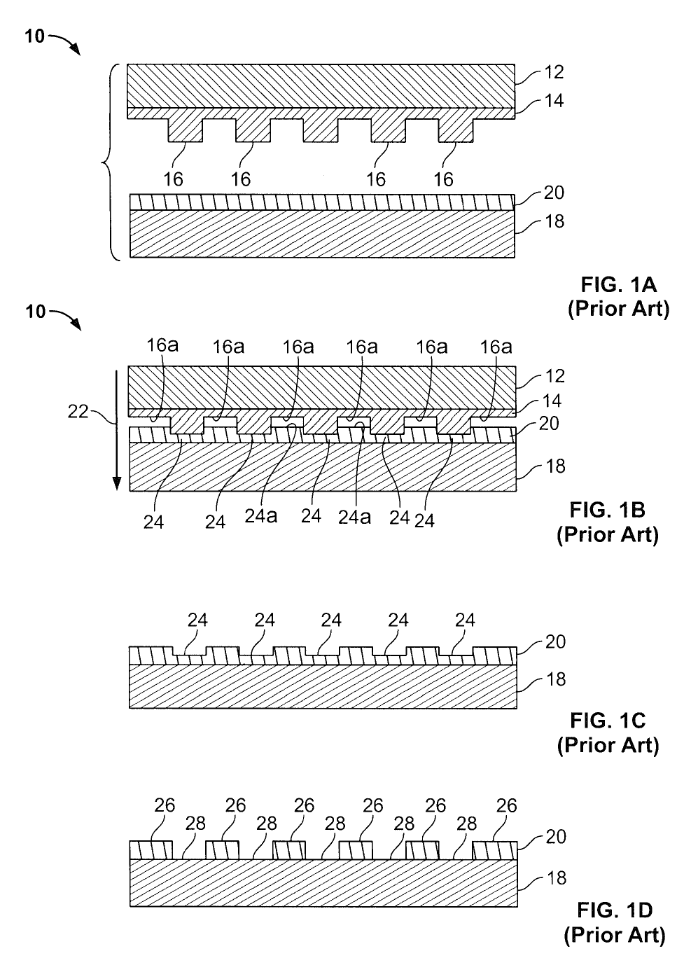

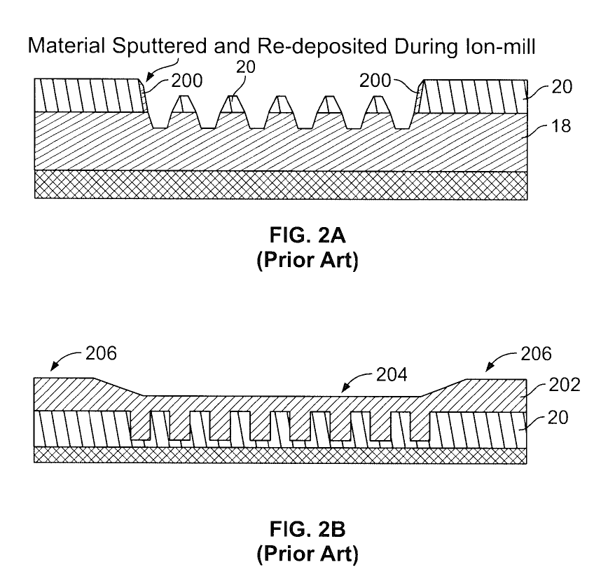

### DETAILED DESCRIPTION OF THE INVENTION

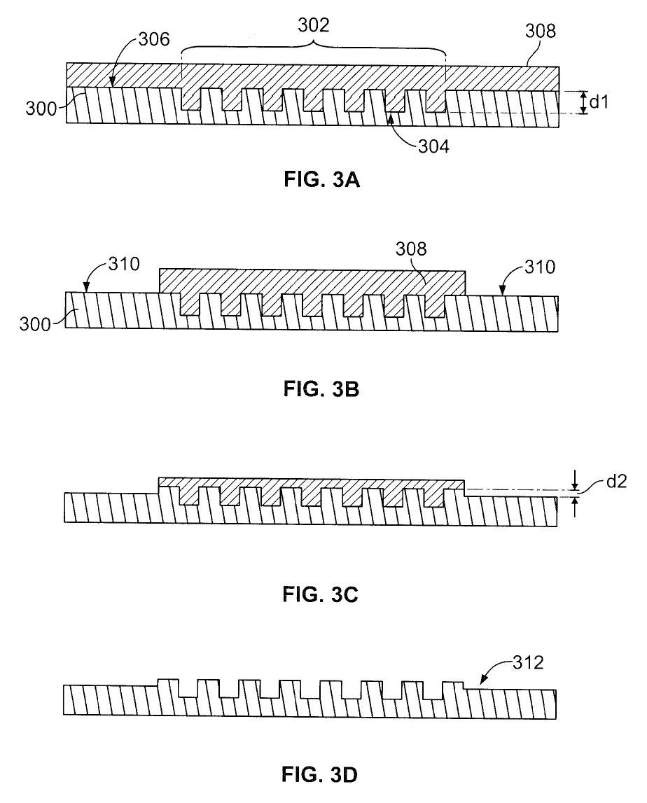

FIGS. 3A-3D show a sequence of steps that may be utilized in fabricating a recessed imprint template in accordance with the concepts of the present invention.

As shown in FIG. 3A, the process begins with the formation of a pattern in an interior region 302 of a template master substrate 300. The pattern is formed in accordance with conventional template fabrication techniques (e.g., e-beam lithography, lift-off, etch or direct-etch) and includes one or more features 304 that extend to a first depth d₁ below an upper planar surface 306 of the template master substrate 300. A mask 308 is then formed over the pattern region 302 of the master substrate 300 as well as over peripheral “field” regions 310 of the master substrate 300. The material of the template master substrate is selected to be hard relative to the thin film layer, such as a thermoplastic or UV-curable resist material, that is to be imprinted. Suitable materials for use as the master substrate include metals, dielectrics, semiconductors, ceramics and composite materials, with quartz, silicon or silicon oxide on a silicon substrate being typical.

Next, as shown in FIG. 3B, the mask 308 is patterned to expose the field regions 310 of the upper planar surface of the master substrate 300 at the border interface between the interior patterned region 302 and the peripheral field region 310.

As shown in FIG. 3C, the mask 308 is then used to etch the field region 310, using for example reactive ion etching (RIE) or wet-chemical etching, to a second depth d₂ below the upper planar surface of the master substrate 300, the second depth d₂ being less than the first depth d₁. The second depth d₂ is typically 10-90% of the first depth d₁.

The mask 308 is then removed utilizing conventional techniques to provide an imprint template 312 having a recessed field region, as shown in FIG. 3D.

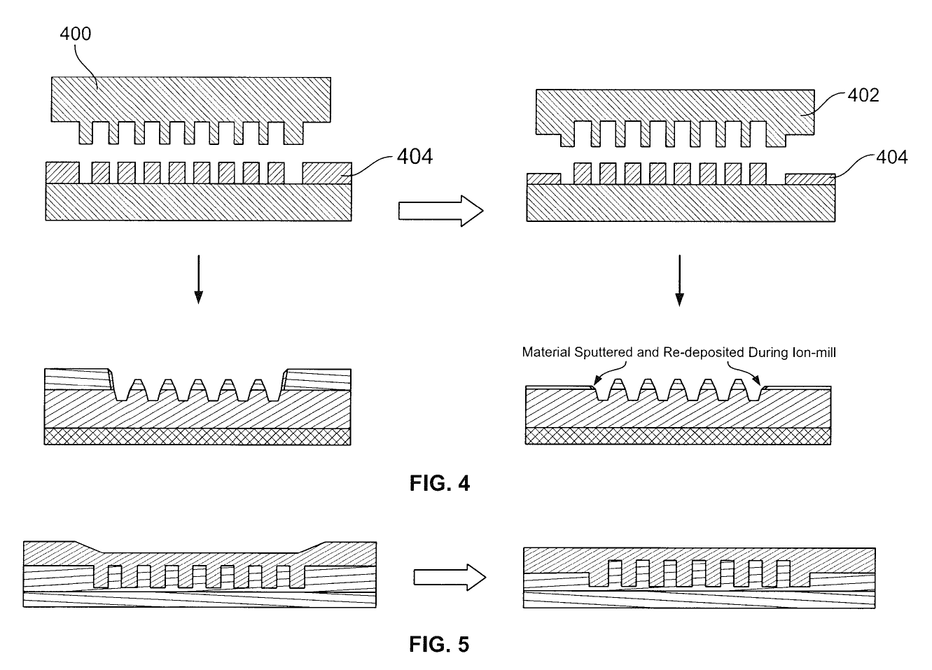

FIG. 4 shows a comparison between utilization of a conventional imprint template 400 and a recessed field imprint template 402 in accordance with the present invention in the formation of a pattern in a resist layer 404 in an ion mill process. As shown in FIG. 4, with reduced resist thickness in the field region bordering the patterned region, sidewall re-deposition during an ion mill process is minimized.

FIG. 5 shows a comparison between utilization of a conventional imprint template and a recessed field imprint template in accordance with the present invention in the formation of a patterned resist layer in a planarization/etch-back process. As shown in FIG. 5, in a planarization/etch-back process, thinner resist in the field helps to achieve a flat surface by compensating for the thickness variation caused by different filling ratios.

Only preferred embodiments of the present invention are shown and described in the present disclosure. It is to be understood that the present invention is capable of use in various other combinations and environments and is capable of changes and modifications within the inventive concepts as expressed herein.

What is claimed is:

1. A method of forming an imprint template suitable for utilization in imprint lithography, the method comprising:
providing a template master substrate having a planar surface;
forming a pattern in an interior region of the planar surface, the pattern including at least one feature that extends to a first depth in the master substrate below the planar surface;
forming a mask over the interior region of the planar surface to expose a peripheral field region of the planar surface;
etching the field region to a second depth in the master substrate below the planar surface that is less than the first depth; and
removing the mask to provide an imprint template having a recessed field region.

2. The method of claim 1, wherein the second depth is 10-90% of the first depth.

3. The method of claim 1, wherein the material of the template master substrate is selected from the group consisting of metals, dielectrics, semiconductors, ceramics and composites thereof.

4. The method of claim 1, wherein the material of the template master substrate is selected from the group consisting of quartz, silicon, silicon dioxide on a silicon substrate and composites thereof.

5. The method of claim 1, wherein the step of forming a pattern in an interior region of the planar surface comprises e-beam lithography, lift-off, etch or direct etch.

6. The method of claim 1, wherein the step of etching the field region comprises reactive ion etching (RIE) or wet-chemical etching.

7. An imprint template suitable for utilization in imprint lithography, the imprint template being formed from a template master substrate having a planar surface, the imprint template comprising:
an interior region of the template master substrate having a pattern formed therein that includes one or more features that extend to a first depth below the planar surface; and
a peripheral field region of the template master substrate that extends to a second depth below the planar surface that is less than the first depth, thereby providing an imprint template having a recessed field region.

8. The imprint template of claim 7, wherein the material of the template master substrate is selected from the group consisting of metals, dielectrics, semiconductors, ceramics and composites thereof.

9. The imprint template of claim 7, wherein the material of the template master substrate is selected from the group consisting of quartz, silicon, silicon dioxide on a silicon substrate and composites thereof.

10. The imprint template of claim 7, wherein the second depth is 10-90% of the first depth.

11. A method of forming an imprint template for utilization in imprint lithography, the method comprising:
providing a template master substrate having a planar surface;
forming a mask over an interior region of the planar surface to expose a peripheral field region of the planar surface;
etching the field region to a first depth below the planar surface;
removing the mask to expose the interior region of the planar surface;
forming a pattern in the interior region of the planar surface, the pattern including at least one feature that extends to a second depth below the planar surface, the second depth being greater than the first depth, thereby providing an imprint template having a recessed field region.

12. The method of claim 11, wherein the first depth is 10-90% of the second depth.

13. The method of claim 11, wherein the material of the template master substrate is selected from the group consisting of metals, dielectrics, semiconductors, ceramics and composites thereof.

14. The method of claim 11, wherein the material of the template master substrate is selected from the group consisting of quartz, silicon, silicon dioxide on a silicon substrate and composites thereof.

15. The method of claim 11, wherein the step of forming a pattern in the interior region of the planar surface comprises e-beam lithography, lift-off, etch or direct etch.

16. The method of claim 11, wherein the step of etching the field region comprises reactive ion etching (RIE) or wet-chemical etching.
